(19) United States
(12) Patent Application Publication
(10) Pub. No.: US 2013/0249359 A1
(43) Pub. Date: Sep. 26, 2013

(54) SERVER CABINET

(71) Applicant: XIAN-XIU TANG, Shenzhen City (CN)

(72) Inventor: XIAN-XIU TANG, Shenzhen City (CN)

(73) Assignees: HON HAI PRECISION INDUSTRY CO., LTD., Tu Cheng (TW); HONG FU JIN PRECISION INDUSTRY (ShenZhen) CO., LTD., Shenzhen City (CN)

(21) Appl. No.: 13/441,949

(22) Filed: Apr. 9, 2012

(30) Foreign Application Priority Data
Mar. 22, 2012 (CN) 201210077826.9

(51) Int. Cl. H05K 5/02; H05K 7/18

(52) U.S. Cl. 312/223.2

(57) ABSTRACT

A server cabinet includes a rack with two opposite sidewalls, and two rails fixed to the sidewalls. A receiving space is formed between each rail for receiving a server. A shielding member is rotatably connected to one of the rails, adjacent to an inlet of the receiving space, to shield the receiving space. An elastic member is resiliently sandwiched between the shielding member and the corresponding rail, to give resistance to the shielding member to rotate outward to shield the receiving space. A first stopping portion extends out from the rail for stopping the shielding member.

### BACKGROUND

1. Technical Field

The present disclosure relates to a server cabinet.

2. Description of Related Art

A server cabinet includes a receiving space for stacking a plurality of servers. When the server is removed from the server cabinet, an opening is left in the server cabinet and should be shielded, otherwise the air outside the server cabinet flows into the cabinet to interfere with the normal airflow in the server cabinet and possibly impair heat dissipation in the server cabinet.

### BRIEF DESCRIPTION OF THE DRAWINGS

Many aspects of the embodiments can be better understood with reference to the drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of an exemplary embodiment of a server cabinet, together with a server.

FIG. 2 is an enlarged view of the circled portion II of FIG. 1.

FIG. 3 is an enlarged view of the circled portion III of FIG. 1.

FIG. 4 is an assembled, isometric view of FIG. 1.

FIG. 5 is an enlarged view of the circled portion V of FIG. 4.

### DETAILED DESCRIPTION

The present disclosure, including the accompanying drawings, is illustrated by way of examples and not by way of limitation. It should be noted that references to “an” or “one” embodiment in this disclosure are not necessarily to the same embodiment, and such references mean at least one.

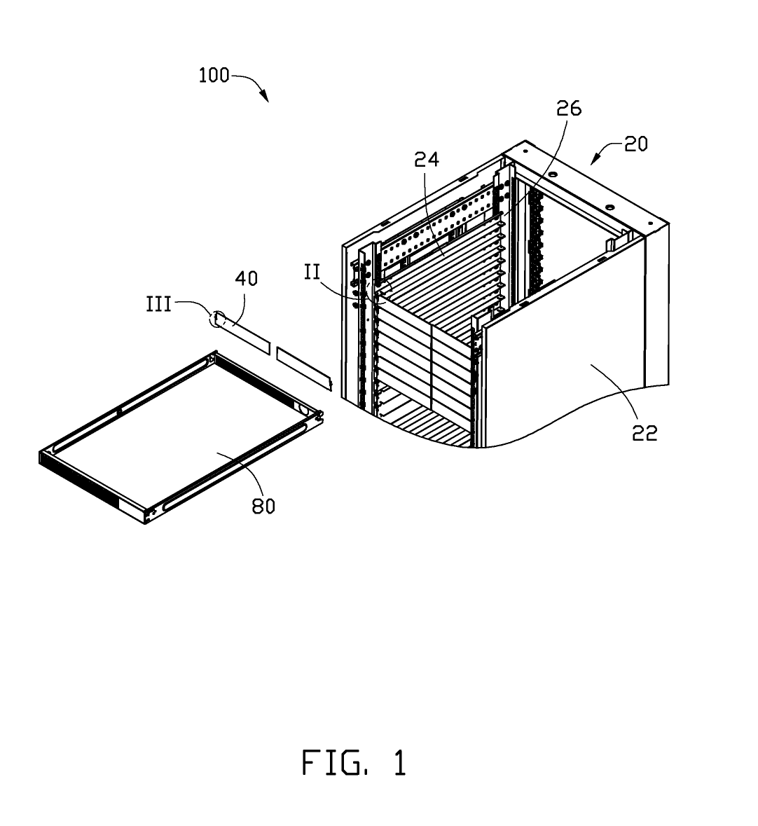

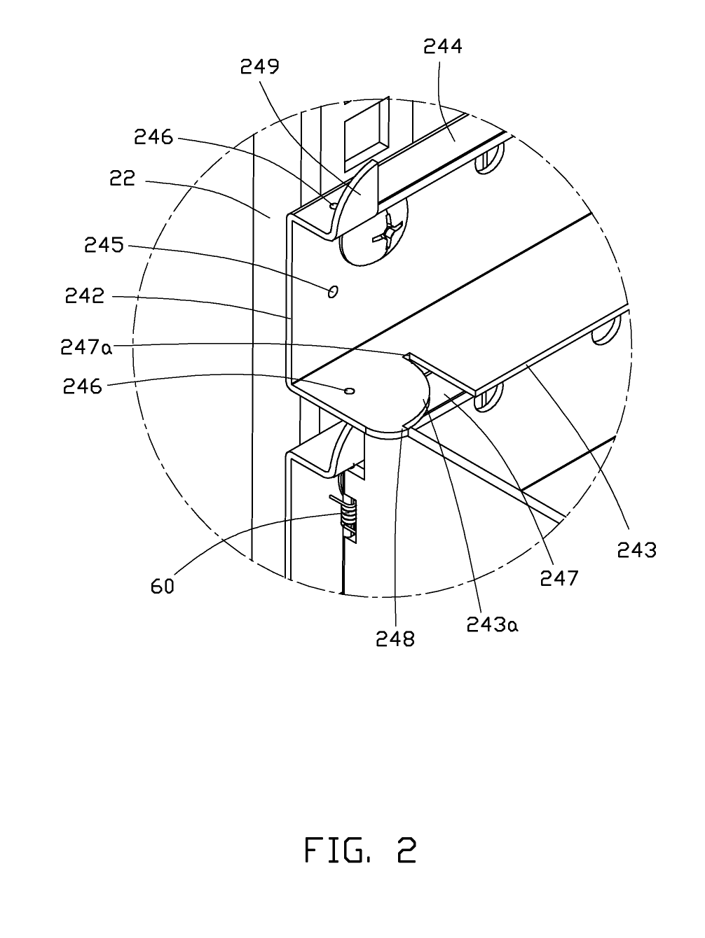

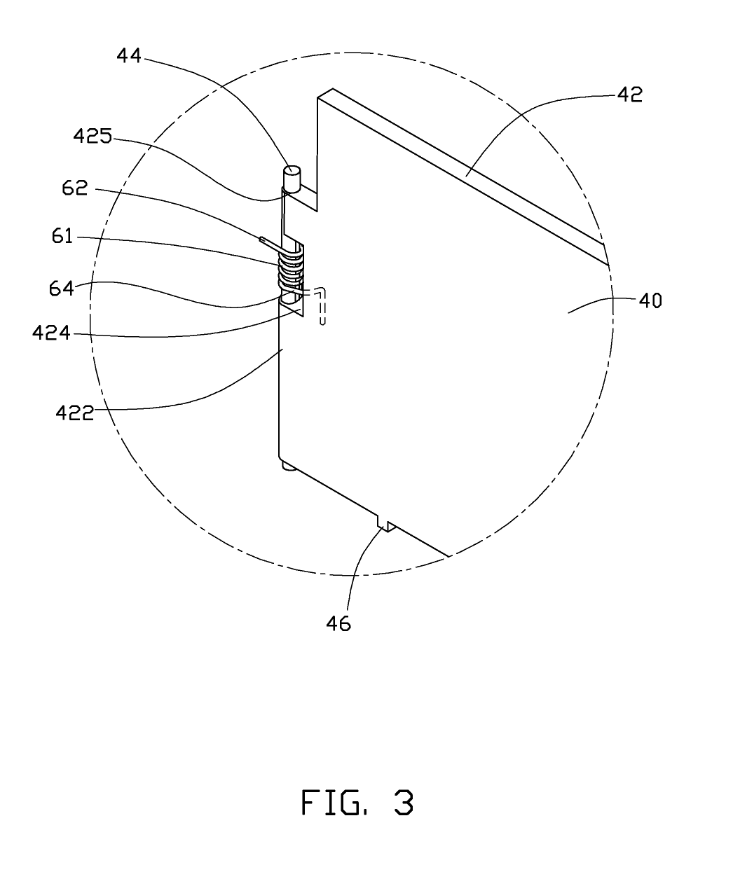

FIGS. 1-3, is an exemplary embodiment of a server cabinet 100 including a rack 20, a plurality of pairs of shielding members 40, a plurality of elastic members 60, and a plurality of servers 80.

The rack 20 includes two opposite sidewalls 22 and a plurality of rails 24 respectively mounted to inner sides of the sidewalls 22. A receiving space 26 is formed between each pair of rails 24 for receiving a server 80.

Each rail 24 includes a rectangular connecting plate 242 fixed to the corresponding sidewall 22, a supporting plate 243 perpendicularly extending in from a bottom side of the connecting plate 242, and a positioning plate 244 perpendicularly extending in from a top side of the connecting plate 242 opposite to the supporting plate 243. A width of the supporting plate 243 is larger than a width of the positioning plate 244. A front end of the connecting plate 242 defines a latching hole 245. Front ends of the supporting plate 243 and the positioning plate 244 each define a fixing hole 246. A guiding slot 247 is defined in the supporting plate 243. A front portion of the guiding slot 247 is quarter-circled, thus a quarter-circled guiding portion 243a is formed from the supporting plate 243 neighboring the guiding slot 247. A circle center of the guiding portion 243a is located at the fixing hole 246. A first stopping portion 248 protrudes in from the supporting plate 243, at a front end of the guiding portion 243a, along a direction perpendicular to the sidewall 22. A second stopping portion 247a is formed on an end wall bounding the guiding slot 247, at a rear end of the guiding portion 243a and adjacent to the connecting plate 242. A tab 249 perpendicularly protrudes up from the front end of the positioning plate 244, parallel to the connecting plate 242.

Each shielding member 40 includes a substantially rectangular shielding panel 42, and two spaced blocks 422 extending out from a first end of the shielding panel 42. The blocks 422 and the shielding panel 42 cooperatively bound a cutout 424. The blocks 422 define two through holes 425 communicating with the cutout 424, and aligning with each other. A protrusion 46 extends down from the shielding panel 42, adjacent to the through holes 425. A distance between the protrusion 46 and the adjacent through hole 425 is substantially equal to a distance between the fixing hole and the guiding portion 243a of the supporting plate 243.

In the embodiment, each elastic member 60 is a torsion spring. The elastic member 60 includes a helical main body 61, a first pin 62 extending out from a first end of the main body 61, and a second pin 64 extending out from a second end of the main body 61.

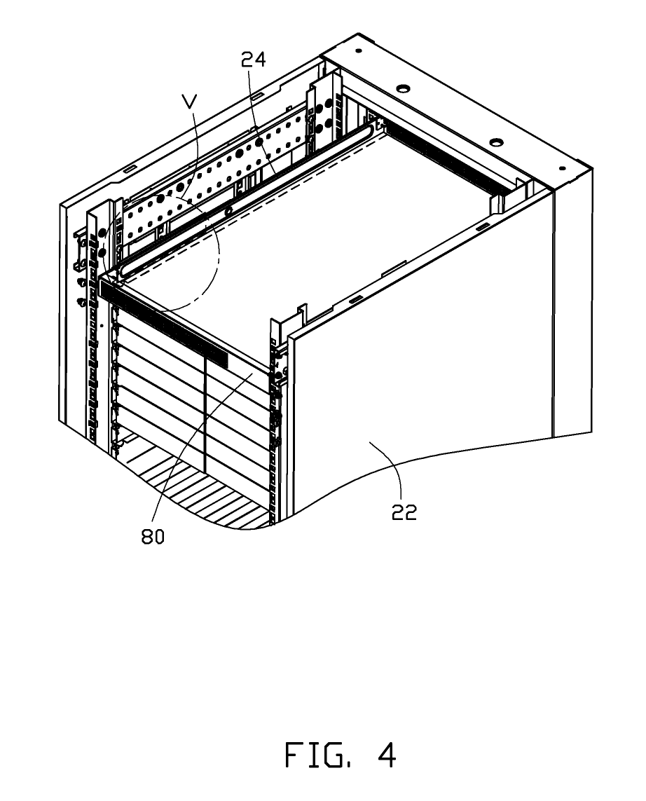

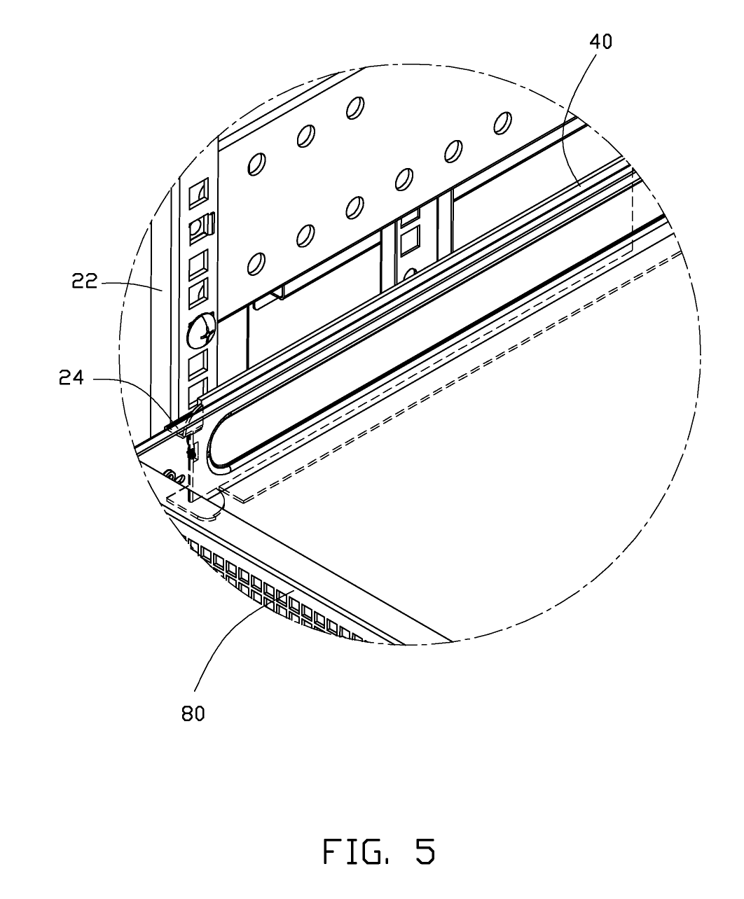

FIG. 4 and FIG. 5, show in assembly, the elastic member 60 is received in the cutout 424, the second pin 64 of the elastic member 60 abuts against the shielding panel 42. The combination of the shielding member 40 and the elastic member 60 is received in the corresponding rail 24, between the supporting plate 243 and the positioning plate 244. The first pin 62 is inserted into the latching hole 245, and the protrusion 46 is slidably received in the guiding slot 247. A shaft 44 extends through the through holes 425 of the blocks 422 and the main body 61 of the elastic member 60. Two opposite ends of the shaft 44 are fixed in the corresponding fixing holes 246. The shielding member 40 rotates about the shaft 44. The elastic member 60 is resiliently sandwiched between the shielding panel 42 and the corresponding rail 24, to give resistance to the shielding member 40 to rotate substantially perpendicular to the sidewall 22. Therefore, the protrusion 46 is slid in the guiding slot 247 blocked by the first stopping portion 248. Second ends of each pair of shielding members 40 opposite to the corresponding blocks 422 are lapped with each other, to shield the receiving space 26.

In assembly of the server 80 to the rack 20, the server 80 is inserted into the corresponding receiving space 26 from the front end of the rack 20. An end side of the server 80 slidably abuts against the shielding panels 42, to give resistance to the shielding members 40 to rotate inward about the corresponding shafts 44, deforming the elastic members 60. The protrusions 46 are slid in the corresponding guiding slot 247 along the corresponding guiding portion 243a from the first stopping portion 248 to the second stopping portion 247a. A bottom side of the server 80 is slidably supported on the supporting plates 243, and two opposite sides of the server 80 are slidably engaged with the corresponding tabs 249, until the shielding panels 42 rotate to be parallel to the connecting plates 242. The protrusions 46 are blocked by the corresponding second stopping portions 247a. Thus, the server 80 is mounted within the rack 20.

When detaching each server 80 from the rack 20, the server 80 is pulled out from the corresponding receiving space 26. The elastic members 60 are restored to give resistance to the shielding members 40 to rotate outward. The protrusions 46 are slid in the corresponding guiding slot 247 along the corresponding guiding portion 243a from the second stopping portions 247a to the first stopping portions 248, until the protrusions 46 are blocked by the corresponding first stopping portions 248. Thus, the shielding members 40 shield the receiving space 26.

In another embodiment, a shielding member 40 having a length equal to a width of the receiving space 26 replaces the pair of shielding members 40. The shielding member is rotatably connected to an end of one of a corresponding pair of rails 24, to shield the receiving space 26.

While the disclosure describes examples and embodiments, it is to be understood that the disclosure is not limited thereto. On the contrary, the disclosure is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A server cabinet, comprising:
a rack with two opposite sidewalls;
two rails respectively fixed to inner sides of the sidewalls, the rails cooperatively bound a receiving space for receiving a server;
a shielding member comprising a first end rotatably connected to a front end of one of the rails near an inlet of the receiving space; and
an elastic member resiliently sandwiched between the shielding member and the corresponding rail, to give resistance to the shielding member to rotate to shield the receiving space, wherein a protrusion extends from the shielding member, a first stopping portion extends out from the rail, for stopping the shielding member when the shielding member rotates to a position shielding the receiving space.

2. The server cabinet of claim 1, wherein each rail comprises a connecting plate fixed to the corresponding sidewall, a supporting plate perpendicularly extending out from a bottom side of the connecting plate, and a positioning plate perpendicularly extending out from a top side of the connecting plate, the shielding member comprises a shielding panel rotatably connected between the supporting plate and the positioning plate with a first end, the elastic member is sandwiched between the connecting plate and the shielding panel.

3. The server cabinet of claim 2, wherein two spaced blocks extend out from the first end of the shielding panel, the blocks define two through holes aligning with each other, the supporting plate and the positioning plate define two opposite fixing holes, a shaft extends through the through holes, and two ends of the shaft are respectively fixed in the fixing holes.

4. The server cabinet of claim 3, wherein a cutout is defined between the blocks, the elastic member is received in the cutout.

5. The server cabinet of claim 5, wherein the elastic member is a torsion spring.

6. The server cabinet of claim 5, wherein the elastic member comprises a main body received in the cutout and fitted about the shaft, a first pin extending out from a first end of the main body to abut against the connecting plate, and a second pin extending out from a second end of the main body to abut against the shielding panel.

7. The server cabinet of claim 3, wherein a guiding slot is defined in the supporting plate around the fixing hole, the supporting plate forms a quarter-circled guiding portion neighboring the guiding slot, the protrusion of the shielding member extends down from the first end of the shielding panel and is slidably received in the guiding slot to move along the guiding portion the first stopping portion is formed at a first end of the guiding slot near the inlet of the receiving space.

8. The server cabinet of claim 7, wherein a second stopping portion is formed on the supporting plate at a second end of the guiding slot, the protrusion is operable to be blocked by the second stopping portion when the shielding panel is rotated to the corresponding rail.
